(19) United States
(12) Patent Application Publication
(10) Pub. No.: US 2025/0341021 A1
(43) Pub. Date: Nov. 6, 2025

(54) FABRICATION OF LARGE AREA RADIATION DETECTORS AND SHIELDING VIA FIELDASSISTED SINTERING TECHNOLOGY (FAST)

(71) Applicant: THE PENN STATE RESEARCH FOUNDATION, University Park, PA (US)

(72) Inventors: Douglas E. Wolfe, University Park, PA (US); Patrict Albert, University Park, PA (US); Justin Reiss, University Park, PA (US)

(21) Appl. No.: 18/865,726

(22) PCT Filed: May 15, 2023
(86) PCT No.: PCT/US2023/022246

§ 371 Date: Nov. 14, 2024

Related U.S. Application Data
(60) Provisional application No. 63/342,237, filed on May 16, 2022.
(60) Provisional application No. 63/382,366, filed on Nov. 4, 2022.

(51) Int. Cl. C30B 28/02; C30B 29/12; G21F 1/10; H10F 71/00

(52) U.S. Cl. CPC C30B 28/02; C30B 29/12; G21F 1/103; H10F 71/121

(57) ABSTRACT

A method of fabricating a polycrystalline crystal of a radiation sensitive material used for radiation detectors or shielding includes providing constituent powders or a single crystal material of the radiation sensitive material or a mixed combination thereof, forming a single phase powder of the radiation sensitive material via solid-state thermochemical and/or thermomechanical reaction between constituent powders or milling the single crystal material of the radiation sensitive material into powders, and pressing the single phase powder of the radiation sensitive material via Field Assisted Sintering Technology to form a pellet, component or structure of the polycrystalline radiation sensitive material.

### CROSS REFERENCE TO RELATED APPLICATIONS

This application claims priority from U.S. Provisional Patent Application Ser. No. 63/342,337, filed on May 16, 2022, and U.S. Provisional Patent Application Ser. No. 63/382,366, filed on Nov. 4, 2022, the entire content of both are incorporated herein by reference in their entirety.

### GOVERNMENT SPONSORSHIP

This invention was made with government support under Grant No. HDTRA1-20-2-0002 Awarded by the Defense Threat Reduction Agency. The Government has certain rights in the invention.

### FIELD OF THE INVENTION

The following invention detailed is a novel manufacturing process for fabricating large area radiation detectors and shielding. This will allow for both increased energy resolution detectors and lightweight high-Z material shielding devices that rivals the current state-of-the-art at a fraction of the cost. Field Assisted Sintering Technology (FAST) is a relatively new manufacturing technique that is capable of consolidating powders with short sintering times to have a tailored grain size and high density. The invention focuses on the fabrication of novel radiation sensitive materials and high-Z materials, for high-energy photon detection and protection against neutrons/photons, respectively.

### BACKGROUND OF THE INVENTION

In the complex geopolitical environment of today, it is extremely important for the international community to have: 1) high energy resolution X-ray, gamma-ray, and α-particle detection capabilities and 2) the ability to protect civilians and first responders from neutron and high-energy radiation with lightweight, cost effective shielding. Novel manufacturing of state-of-the-art radiation detection and shielding devices will also prevent nuclear proliferation, validate international treaties, and stop the discharge of weapons of mass destruction. In addition, high-energy resolution detectors and lightweight shielding can open the doors for novel medical imaging devices and radiative therapy. Currently, the development of next generation radiation sensitive materials and devices is heavily constrained by challenges associated with manufacturing limitations and scalability.

Current state of the art γ-ray solid-state detectors can reach energy resolutions of <0.7%; however, significant obstacles limit their widespread implementation: 1) high costs associated with raw material and single crystal growth methods which can be cost prohibitive to the Department of Defense and/or medical community, 2) limited small area detectors, and 3) liquid nitrogen cooling requirements, etc. Extensive research has focused on replacing HPGe detectors with a semiconductor that can be operated at room temperature. This research has primarily focused on searching for semiconductors with the following properties: 1) high atomic number (Z>40) for high photon attenuation; 2) large band gap (E_{g}>1.5 eV) to limit thermal noise; 3) high mobility-lifetime product (μτ>10⁻⁴ cm²/V); and 4) low dielectric constant to ensure low capacitance.⁵ The current leading candidate for room temperature γ-ray detection is Cadmium Zinc Telluride (CZT) which has demonstrated ˜1% energy resolution to date. CZT has several critical advantages including large band gap (E_{g}˜1.65 eV), high μτ product (10⁻² cm²/V), high average Z, and high resistivity (10¹¹ Ωcm). However, substantial challenges have currently plateaued further development of CZT based detectors. The raw materials used in CZT are inherently expensive, making CZT detectors even more expensive than HPGe. Single crystal growth of CZT is currently limited to only 15 mm thick, even while using melt based techniques (typically Bridgman). This is primarily due to poor congruent melting of the constituent materials and subsequent diffusion of Zn, which results in non-uniform Zn distribution through the length of the single crystal. Additionally, excess Te precipitates during growth. The Te precipitation deteriorates detector performance and yields further raising the cost of CZT detectors as yields are very low. There is current demand for the development of a manufacturing technology that can realize low cost γ-ray detector devices for more widespread implementation compared to single crystal melt growth.

For X-ray detection and imaging applications, polycrystalline thin film semiconductors have been implemented in the form of flat panel X-ray imagers. These devices are typically comprised of an active amorphous selenium (a-Se) thin layer deposited on top of a transistor array, and have reached X-ray sensitivities of 20 μC/Gy cm². Although economical, there are several fundamental challenges associated with a-Se that limit its use to fairly low energy X-ray applications. Compared to competing scintillating technologies, a-Se has an order of magnitude lower photon attenuation at high energies, which renders the technology not viable for higher energy X-ray detection. These higher energies are necessary for chest and torso imaging. For chest and torso X-rays, scintillator arrays are currently used which have a much lower detection efficiency and sensitivity than what is possible with solid-state detectors. This results in an overall higher X-ray dose per chest/torso image, which can have long term negative impacts on the patient with repeated exposure. The development of a solid-state detector with a high mass attenuation coefficient and low manufacturing cost can enable the broader use of low-dose, high energy X-ray imaging.

In conjunction, shielding applications have practically limits against neutron and photons because their effectiveness is dependent on adding thicker layers of high-Z materials to increase stopping power of the incoming ionizing radiation. This leads to heavy, hard to manage components. There is currently a technology gap for the fabrication of novel low cost, large area, high resolution, room temperature X-ray/gamma-ray/α-particle detectors and for the fabrication of novel lightweight, robust shielding. Advancing the ability to fabricate large area, radiation sensitive materials could have a disruptive impact across both the medical and national security communities.

Recently, metal halide perovskites (MHPs) and metallic containing nanostructure materials such as PbTe, CdTe, PbSe, and CdSe have generated a huge interest in the academic community for next radiation detectors and shielding applications, respectively. MHPs (with a prototypic cubic crystal structure and/or subsequent displacive phase transitions/transformations including: tetragonal, orthorhombic, rhombohedral, monoclinic, trigonal, hexagonal, and triclinic) have the general chemical formula of ABX₃ where A is a 1⁺ cation (methylammonium⁺, formamidinium⁺, Rb⁺, or Cs⁺), B is a 2⁺ metal cation (Pb²⁺, Sn²⁺, Bi²⁺), and X is a 1⁻ halogen (Cl⁻, Br⁻, I⁻). Because the majority of these MHP compositions have a high average Z number, they have the potential to stop high energy radiation with high efficiency. Combined with a fairly high intrinsic bandgap (˜0.1-5.0 eV), these ionic crystal semiconductors have the potential to have high stopping power with low noise. While research into MHP solar cells has developed rapidly and is on the verge of commercialization, radiation detection devices based on MHPs are still in a relatively infant research stage. For shielding applications, the device must have high attenuation of incident photons. Currently, to improve shielding capabilities of high-Z materials, devices use greater thicknesses to increase the interaction probability of damaging quanta with the protective medium. The resulting devices are heavy and impractical, and necessitate the development of a novel processing technique capable of manufacturing a design that will yield lightweight, robust shielding. It is hypothesized that using nanostructured materials, or materials with nanoscale microstructural features, could lead to an enhanced interaction between radiation and the confined nanoparticles or nanograins. This interaction phenomenon would more effectively attenuate the incident photons and allow for the design flexibility of lightweight, robust shielding.

Several problems limit the widespread implementation of these aforementioned materials and devices. MHPs have a high cost associated with the high purity raw materials and the Bridgman growth process used to fabricate single crystals, and limitations on the crystal size. While further progression of this type of single crystal growth process is technologically relevant, there leaves room for a more cost-effective synthesis approach that also opens the door to larger area detectors. Recent research into polycrystalline pellets fabricated by uniaxial pressing MHP powder/micro-crystals followed by a post process anneal has been implemented for use as a solid-state X-ray detector. These studies on MAPbI₃ and FAPbBr₃ have shown orders of magnitude improvement in X-ray sensitivity over current a-Se detectors. However, publications to date on the consolidation of MHP micro-crystals or powder are fairly limited in scope and have not investigated the effects powder processing and sintering has on microstructure and subsequent X-ray sensitivity. Additionally, conventionally sintering as described in the above publications inherently limits density and grain growth due to a lack of additional energy supplied to the system during the sintering process, resulting in increased porosity, decreased grain size, and overall reduced performance. Current fabrication of radiation shields, designed for but not limited to gamma radiation, can be costly for functionally graded multicomponent high-z materials, thick and heavy for wearable gear, challenging to fabricate nanoscale microstructural features, and expensive to scale to large areas.

### SUMMARY OF THE INVENTION

The embodiments of the present invention provide a method of fabricating a polycrystalline crystal of a radiation sensitive material used for radiation detectors or shielding. The method includes providing constituent powders or a single crystal material of the radiation sensitive material or a mixed combination thereof, forming a single phase powder of the radiation sensitive material via solid-state thermochemical and/or thermomechanical reaction between constituent powders or milling the single crystal material of the radiation sensitive material into powders, and pressing the single phase powder of the radiation sensitive material via Field Assisted Sintering Technology to form a pellet, component or structure of the polycrystalline radiation sensitive material. The pellet can be up to 14″ in diameter.

The milling technique can be used to form the single phase powder of the radiation sensitive material. The milling technique includes ball milling, attrition milling, cryogenic milling, shaker jar milling.

The powder of the radiation sensitive material may be embedded into matrix materials before pressing. The matrix materials may be polymeric fibers or plastics.

The radiation sensitive material can be metal halide perovskites, metal halide double perovskites, wide band gap semiconductors or high-Z materials.

For the example of the radiation sensitive material CsPbBr₃, the constituent powders are CsBr and PbBr. The CsBr powder can be pre-milled so that the CsBr and PbBr powders have a particle size on the same order of magnitude.

The temperature for FAST is in a range of from −100° C. to 0.95T_{M}, where T_{M} is the melting temperature of the material. The pressure for FAST may be in a range of from 0 MPa to 200 MPa.

### BRIEF DESCRIPTION OF THE INVENTION

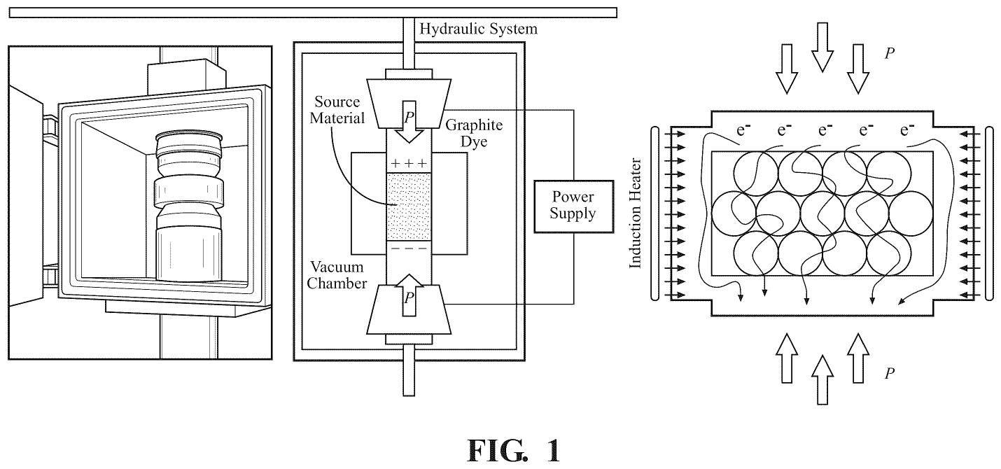

FIG. 1 shows a digital image of a reusable graphite molds inside of the chamber (left), a schematic diagram of field assisted sintering technology (FAST) (middle), and an illustration of electric field induced sintering mechanism (right);

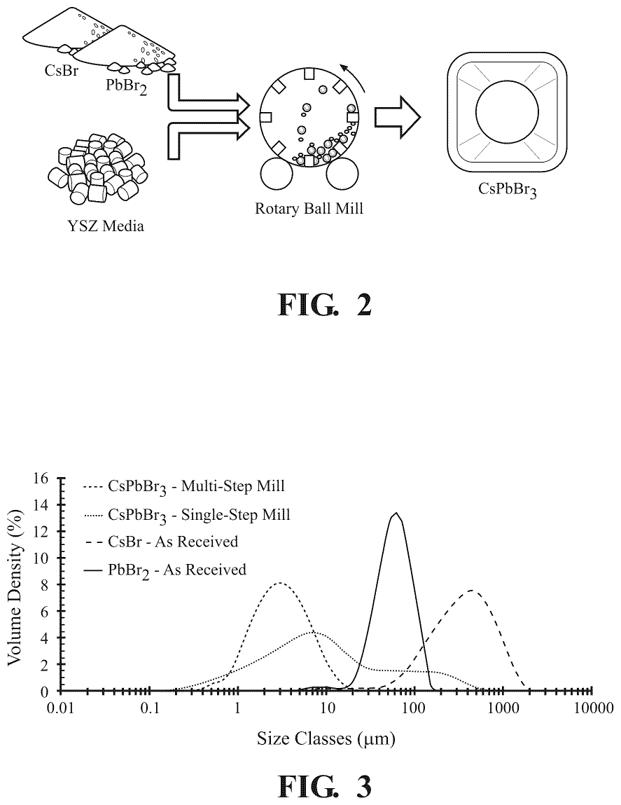

FIG. 2 shows a schematic of a process of CsPbBr₃ powder mechanically synthesized using rotary ball milling;

FIG. 3 shows particle size distribution of as received CsBr and PbBr₂, ball milled CsPbBr₃, and ball milled CsPbBr₃ with CsBr pre-milling step;

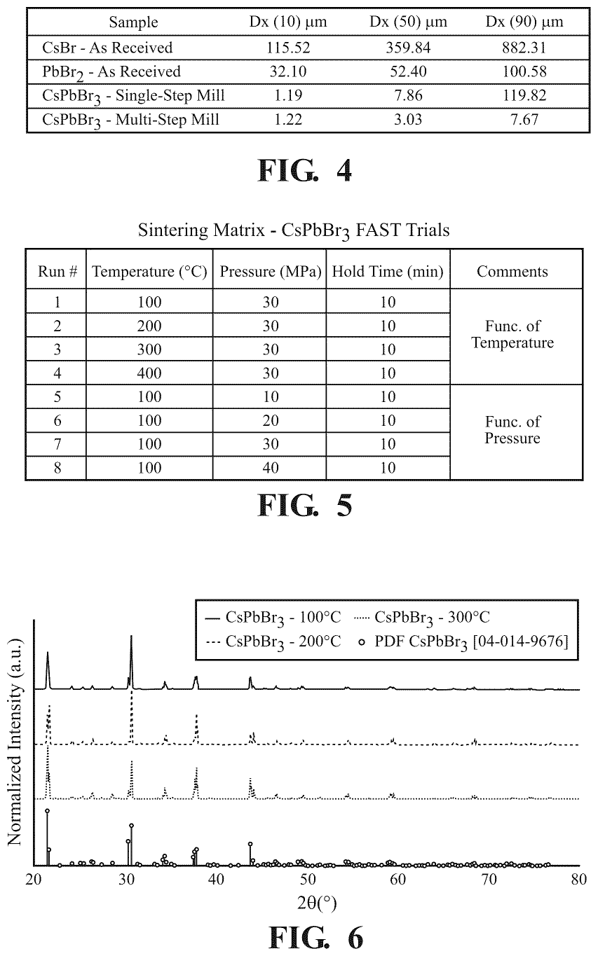

FIG. 4 is a table showing PSD percentiles for as-received and ball milled powders;

FIG. 5 is a table showing 8 FAST trials designed to observe the effects of temperature and pressure on the CsPbBr₃ pellet microstructure

FIG. 6 shows a XRD diffraction pattern of CsPbBr₃ fabricated via FAST as a function of temperature (100, 200, and 300° C.);

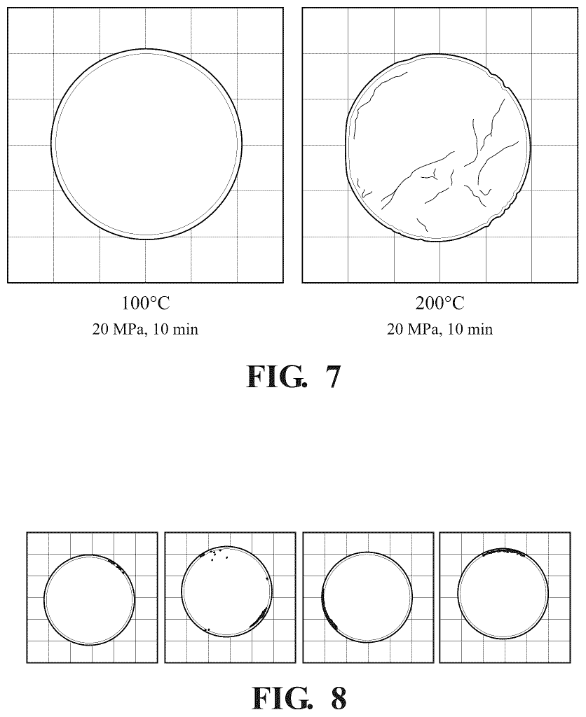

FIG. 7 shows color of a CsPbBr₃ pellet changed from a bright orange at 100° C. to a dark red at 200° C.;

FIG. 8 shows color change of a CsPbBr₃ pellet sintered via FAST as the pressure increases;

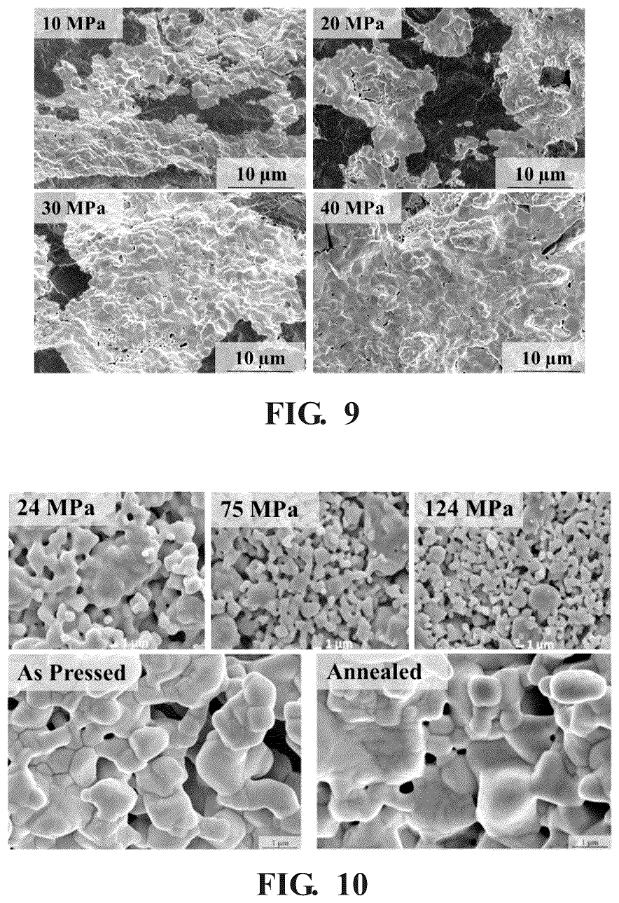

FIG. 9 shows fracture surface SEM micrographs of CsPbBr₃ pellets as a function of applied pressure (All pellets exhibit a bimodal grain size distribution, with the percentage of large modes increasing as a function of applied pressure);

FIG. 10 shows fracture surface SEM micrographs of FAPbBr3 conventionally pressed pellets as a function of increasing pressure and annealing;

FIG. 11 shows fracture surface SEM micrographs of perovskite conventionally sintered pellets and FAST pellets;

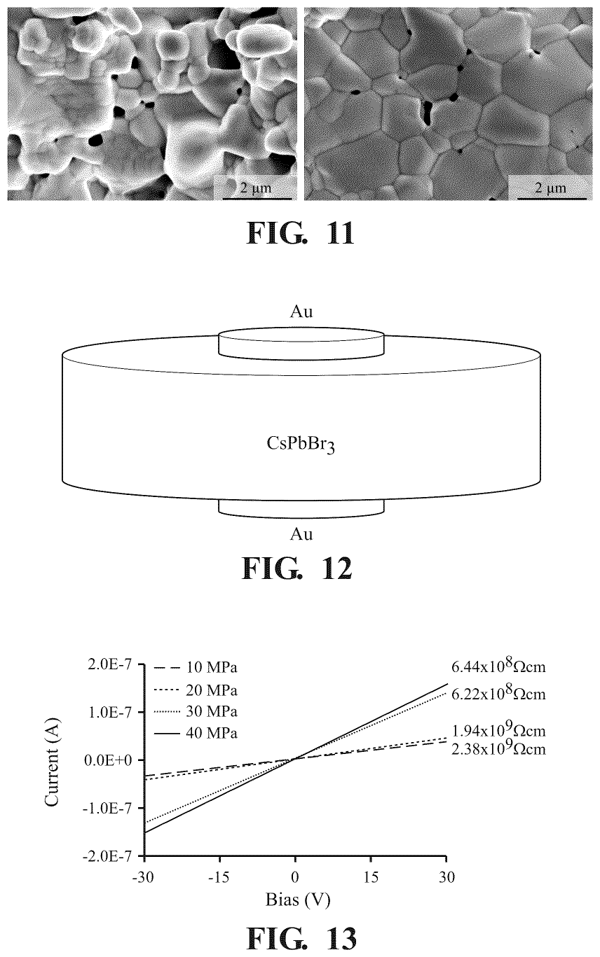

FIG. 12 shows a schematic of vertical Au/CsPbBr₃/Au structure of an Ohmic junction;

FIG. 13 shows a graph of measured resistivity of Au/CsPbBr₃/Au vertical structures as a function of applied pressure during FAST processing;

FIG. 14 shows a schematic of Fermi levels of TiN/CsPbBr₃ contact;

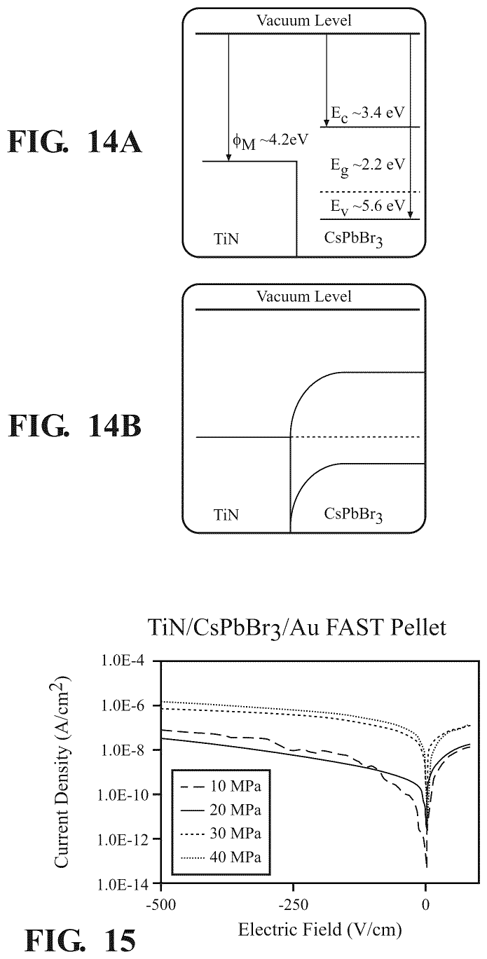

FIG. 15 shows IV characteristics of TiN/CsPbBr₃/Au FAST pellet structures (Rectifying behavior only seen in pellets pressed at 10 and 20 MPa, with higher pressures exhibiting Ohmic behavior);

FIG. 16 shows a plot of dark current vs, applied electric field of a TiN/CsPbBr₃/Au device;

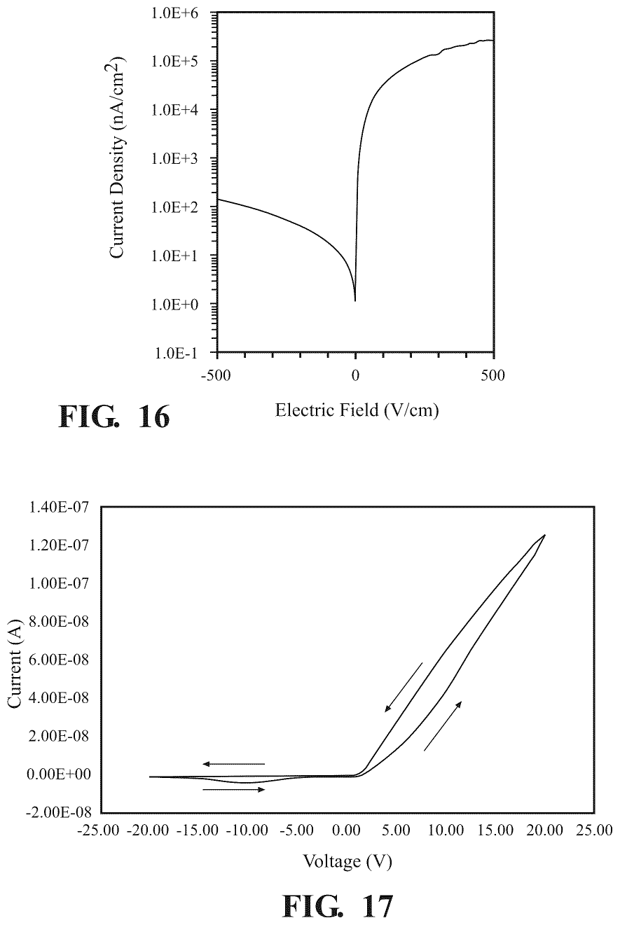

FIG. 17 shows IV characteristics of a TiN/CsPbBr₃/Au device showing a hysteresis behavior as voltage is swept from −20 to +20 V, and back;

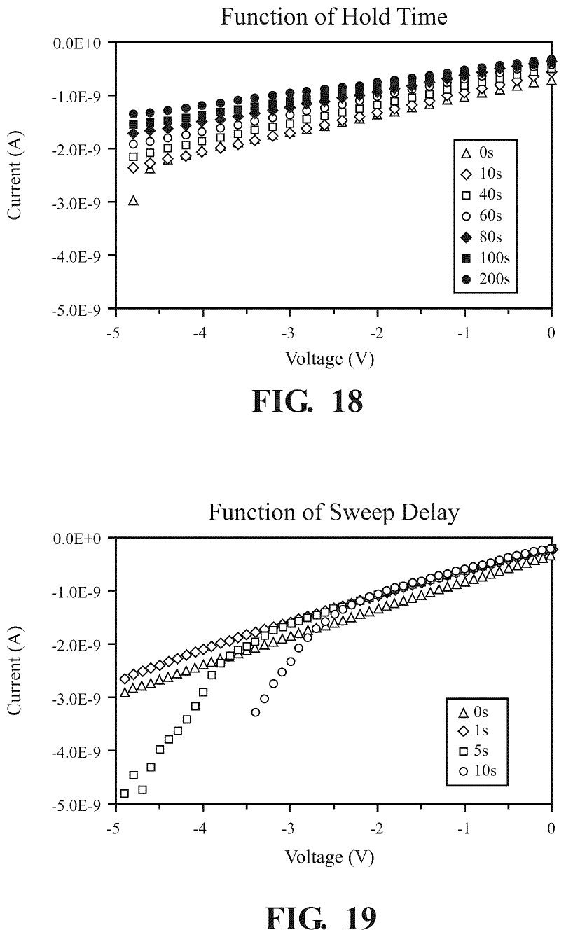

FIG. 18 is a plot showing function of hold time;

FIG. 19 is a plot showing function of sweep delay; and

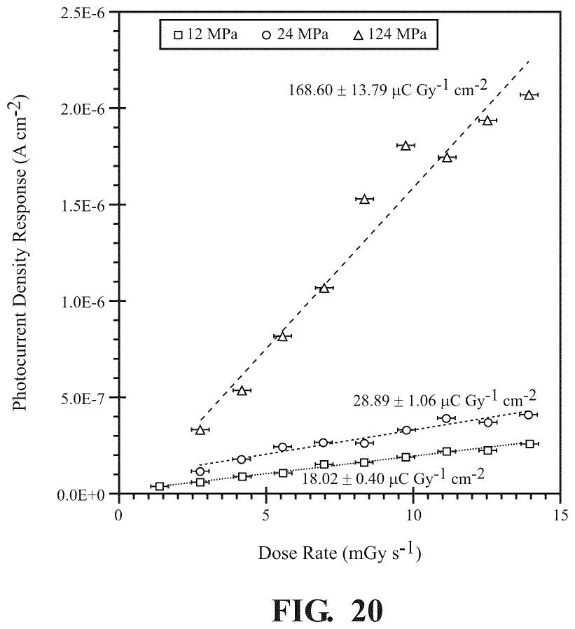

FIG. 20 shows X-ray sensitivity of FAPbBr₃ conventionally sintered pellets as a function of applied pressure.

### DETAILED DESCRIPTION OF THE INVENTION

The presently disclosed technology provides a fabrication pathway for large area and cost effective radiation detectors and shielding by consolidation of powder materials via field-assisted sintering technology (FAST). The powder materials may be of material systems such as metal halide perovskites, double perovskites, wide band gap semiconductors, and high-Z composites.

Any of the proposed material systems can be fabricated by solid-state thermochemical and/or thermomechanical reaction between constituent powders via a variety of techniques including milling, grinding, mixing, etc. to form a single phase powder. Then the single phase powder is pressed to form a pellet via FAST. Optionally, single phase powders are embedded into matrix material (such as polymeric fibers, plastics, etc.) before being pressed into a pellet via FAST.

The powder materials can be synthesized from mixing the constituent materials powder to form single phase powder materials or can be obtained by milling single crystal material into fine powders. The material remains in the solid state throughout the entire manufacturing process. For example, CsPbBr₃ powders can be obtained by mixing CsBr powder and PbBr₂ powder to form single phase CsPbBr₃ powders or by milling single crystal CsPbBr₃ into powders.

The CsBr powder may be pre-milled so that the CsBr and PbBr powders have a particle size on the same order of magnitude. Milling techniques includes ball milling, attrition milling, cryogenic milling, shaker jar milling, etc. In the solid state, mechanical alloying using milling techniques to form single phase CsPbBr₃ powder with uniform particle size distributions. CsPbBr₃ pellets may then be fabricated by consolidation of the CsPbBr₃ powder via FAST.

Field Assisted Sintering Technology (FAST), also known as Spark Plasma Sintering (SPS), has many advantages compared to competitive sintering processes (e.g. Hot Pressing (HP), Hot Isostatic Pressing (HIP), etc.) including higher heat rates and lower processing cycle times. The FAST process involves direct contact heating of the component, resistance heating of the graphite dies, and eddy currents leading to joule heating in conductive material. The powder material is contained in a graphite die with a controllable inert or reactive environment where pressure is applied through a hydraulic system. The combination of pressure, temperature, and localized heating at the grain boundaries result in a high sintering rates, which allow for nano-grained microstructures, compositionally graded structures, and high densities. FAST has the capability to rapidly sinter metals, ceramics, and both metal and ceramic composites. There is also a significant energy saving of 30-40% compared to other sintering techniques.

For the FAST sintering process used in the present disclosure, a typical range of the temperature would be −100° C.−0.95T_{M}, where T_{M} is the melting temperature of the radiation sensitive material. The pressure can range from 0 MPa-200 MPa. Field strength is dependent on die size, die material, powder composition, mass of powder, geometry of component being consolidated, input power, amongst other parameters. The input power will greatly impact the boundary conditions of the applied field strength. The maximum input power is dependent on the FAST system. For example, the prototype system used in the experiment has a 100 kW max applied power.

The pellets fabricated according to the disclosed method can be used for radiation detectors or radiation shielding. A radiation detector may comprise a semiconducting material with two or more electrodes deposited onto the surface. One set of electrodes collects electrons, and the other set collects holes. The electrodes can be deposited in a variety of configurations and geometries, including but not limited to planar electrodes, pixelated electrodes, asymmetric electrodes, imbedded electrodes, multilayered electrodes, p-i-n configured electrodes, etc. The semiconductor material itself has a wide range of potential properties including a band gap ˜0.5-6 eV, resistivity ranging from 10⁶-10¹⁴ Ohm cm, and features the ability to convert absorbed photons into electron-hole pairs.

Once the pellet is fabricated, the surfaces are polished using chemo-mechanical methods in order to obtain a smooth finish. Once polished, the surfaces are passivated (i.e. oxide grown on top of the crystal) using a wide variety of methods including plasma treatments, etching, heat treatments, thermochemical reactions, thin film deposition, atomic layer deposition, etc. Then, electrodes are deposited via physical vapor deposition techniques such as thermal evaporation, electron-beam evaporation, or sputtering. Electrode materials can be comprised of any metal, metal-nitride, metal-carbide, or metal oxide. Examples of electrode materials include, but are not limited to, gold, silver, carbon, titanium, vanadium, chromium, iron, nickel, copper, zinc, gallium, aluminum, silicon, zirconium, niobium, molybdenum, palladium, ruthenium, indium, tin, hafnium tantalum, tungsten, rhenium, iridium, platinum, lead, bismuth, and subsequent nitrides, carbides, oxides, dopants, mixed concentration, etc. Specific nitrides, carbides, and oxides include titanium nitride, vanadium nitride, chromium nitride, tungsten nitride, aluminum nitride, titanium aluminum nitride, zirconium nitride, hafnium nitride, niobium nitride, titanium oxide, chromium oxide, vanadium oxide, iron oxide, copper oxide, zinc oxide, indium oxide, indium tin oxide, tin oxide, aluminum oxide, aluminum zinc oxide, nickel oxide, magnesium zinc oxide, copper chromium oxide, titanium carbide, aluminum carbide, chromium carbide, hafnium carbide, tantalum carbide, tungsten carbide, zirconium carbide, niobium carbide, vanadium carbide, and mixed compositions and dopants thereof.

Radiation detectors and radiation shielding both feature the ability to interact with high energy particles, charge particles, neutrals, neutrons, etc. But what happens after energy is absorbed by the material is different. In a radiation detector, energy is absorbed, resulting in the production of electron-hole pairs. These electron-hole pairs are then extracted from the detector under an applied electric field, and collected by the electrodes. This charge collection allows for the detection of ionizing radiation, particles, neutrons, etc. Radiation detectors require small measured currents under high applied voltage. This is generally dictated by the bulk resistivity of the semiconductor. If the semiconductor has a high enough bulk resistivity (˜10¹⁰⁻¹¹ Ωcm), an ohmic contact structure is preferred. If the semiconductor has a low bulk resistivity (˜10⁸⁻⁹ Ωcm) a rectifying junction is needed. For the example of CsPbBr₃, the rectifying junction is necessary for radiation detection.

In a radiation shield, the primary goal is to absorb, reflect, deflect, or scatter photons, ions, particles, neutrons, etc. The radiation shield may or may not generate electron-hole pairs under irradiation. Collecting electron-hole pairs is not the primary objective of the radiation shield, so there does not need to be a conduction pathway through the bulk to monitor radiation interactions. Radiation shields can take a variety of forms including bulk material, nanostructured material, multilayered material, composite material, nanostructured composite materials, etc.

The disclosed method can lead to room temperature X-ray/gamma-ray/α-particle detectors with high energy resolution and lightweight, durable shielding.

FAST involves different parameters such as temperature, pressure, time and applied electric field, as illustrated in FIG. 1. FAST utilizes high current, low voltage pulsed DC waveforms to rapidly consolidate powder. FAST has a fundamental mechanism typically described by initial neck growth followed by porosity elimination and grain growth. FAST allows for grain size tailoring and can sinter >99% density compacts. Different parameters such as temperature, pressure, time and applied electric field will be investigated herein. Additional energy source (electric field) may lower the critical sintering temperature. Other advantages of using FAST includes extremely short processing time (˜10 minutes) and scalability. For example, components of up to 14″ diameter can be made.

The presently disclosed technology is capable of fabricating large area polycrystalline detectors and shielding via powder synthesis and subsequent FAST processing. The primary material systems of interest are metal halide perovskites, metal halide double perovskites, and high-Z materials.

An example of metal halide perovskites is ABX₃, where A is Cs⁺, MA⁺, FA⁺, B is Pb²⁺, X is Cl⁻, Br⁻, I⁻. Some examples of metal halide double perovskites are Cs₂AgBiBr₆, Cs₂AgBiCl₆, Cs₂AgBiI₆, Cs₂NaBiBr₆, Cs₂NaBiCl₆, Cs₂NaBiI₆, Cs₂InBiBr₆, Cs₂InBiCl₆, Cs₂InBiI₆, and subsequent doped and co-doped structures, and mixed compositions thereof. Some examples of high-Z materials are PbTe, CdTe, Pb, PbO, Bi, Bi₂O₃, PbSe, and CdSe, mixed cation tellurides (A₁₋ₓBₓ)Te, subsequent doped and co-doped structures and mixed compositions thereof. FAST will also be capable of consolidating next generation semiconductor materials including, but not limited to, Cu₃NbSe₄, Cd₇P₄Cl₆, Cu₃TaSe₄, Tl₂SnCl₆, Cu₃TaS₄, Tl₃NbSe₄, Cs₂HfI₆, Tl₃TaSe₄, Tl₃NbS₄, NbS₄Tl₃, Tl₂SnCl₆ and other radiation sensitive materials and wide band gap semiconductors.

### Polycrystalline Semiconductors

Wide band gap polycrystalline semiconductors offer substantially faster processing times, lower costs, and ability to produce large area detectors.

Engineering grain boundary chemistry and imbedding contacts within the polycrystalline structure can reduce effective ut requirements, enabling γ-ray detection.

### Experiments

Initial work has focused on sintering the MHP composition CsPbBr₃ for use as an X-ray detector; however, the fundamentals provided can be expanded to other MHPs, double perovskites, novel wide band gap semiconductors, and high-Z composites for a variety of radiation detection and shielding applications. Based on this initial work, the enhanced dense microstructure can be achieved via FAST compared to conventional sintering techniques, which will likely result in substantial performance benefits including enhanced X-ray sensitivity and γ-ray energy resolution.

FIG. 2 shows that CsPbBr₃ powders were mechanically synthesized using rotary ball milling in order to form single phase powders with uniform particle size distributions PSDs. The as-received CsBr and PbBr₂ powders had substantially different PSDs, with CsBr having a Dₓ(50) of ˜500 μm and PbBr₂ having a Dₓ(50) of ˜50 μm, as shown in FIG. 3. Full reaction between CsBr and PbBr₂ was limited due to substantially larger CsBr particles. This necessitates milling the CsBr first without the PbBr₂ to ensure that the CsBr has a particle size on the same order of magnitude as the PbBr₂. Without PSD matching of the binary powders, the final product will always have excess CsBr particles that have not fully reacted with the PbBr₂ due to the surface area differences which restrict overall reactivity between the two species. After pre-milling the CsBr, PSDs of the CsPbBr₃ were ˜3.03 μm Dₓ(50), with a substantial reduction in the Dₓ(90) from 119 μm to 7.67 μm, as shown in the table in FIG. 4. Additional reduction in PSD can be made by including two milling steps with decreasing media size (10 mm, 2 mm media diameter). Decreasing milling size increases the surface area to powder ratio, thus increasing the amount of media contact with the powder and effectively reducing the average particle size. Milling efforts may also utilize lubrication to prevent particle agglomeration during milling and increase overall milling uniformity.

### Results and Discussion

A series of 8 FAST trials were designed to observe the effects of temperature and pressure on the CsPbBr₃ pellet microstructure.

### 1. Effect of Temperature

First, temperature was varied from 100° C. to 300° C., keeping pressure and time constant at 20 MPa and 10 minutes respectively. From visual observation, it was observed that the color of the pellet changed from a bright orange at 100° C. to a dark red at 300° C., with the 300° C. pellet actually failing and breaking upon cool down, as shown in FIG. 7. The failure of this pellet is thought to be due to the extremely large thermal expansion coefficient of CsPbBr₃ (37.7×10⁶/K) and the subsequent stress buildup during heat up and cool down. XRD was performed on each of the pellets to understand if the changing pellet color was associated with a phase change, as shown in FIG. 6. Two trends are noticeable in the XRD as a function of temperature. First, as temperature increases the FWHM decreases, suggesting that the grain size of the pellets increase with temperature. This is expected as more thermal energy is applied to the system promoting grain growth. More importantly, as temperature increases, noticeable shifts in the peak positions can be observed. If we measure the Δ2θ of the individual spectrum (Δ2θ=PDF-measured peak), as temperature increases, the Δ2θ becomes more negative. It can also be seen that the change in peak shifting increases as a function of angle 2θ, indicating that these shifts are due to compositional variance as opposed to residual stress. Therefore, at the elevated temperatures, the observed negative Δ2θ is due to decreased interplanar spacing, which is likely attributed to increased halide vacancy concentration. This makes intuitive sense for several reasons. Halides are well known for having a fairly low vapor pressure, so there is an increased probability of off gassing halides at 200-300° C. at 3 mTorr. Additionally, a release of halide species would match with visual observations of the color change. As the concentration of halide species in the ionic crystal decreases, the number of strong ionic bonds decreases, resulting in a decreased band gap. For future processing efforts, low temperatures will be used to consolidate powders in order to maintain the wide band gap and decrease the number of point defects.

### 2. Effects of Pressure

As pellets are pressed as a function of pressure, the color darkens very slightly with increasing pressure, as shown in FIG. 8. This is unexpected as the release of halides should be more dependent on temperature which was held constant. XRD diffraction patterns show no distinct peak shifting, suggesting that the halide concentration and stress states between the samples is fairly uniform. The slight color shift might instead be due to slight changes in density which alter the absorption of light. FWHM in the samples decreases slightly as a function of applied pressure, which correlates well with a suspected increase in grain size with increasing pressure.

Fracture surfaces were imaged via SEM to analyze the microstructure of the sintered compacts, as shown in FIG. 9. All of the pellet microstructures exhibit a bimodal grain size distribution. Each mode is highlighted by contrast variation in the SEM fracture surface image, with the darker regimes having smaller (<1 μm) grains and the brighter regimes having larger (˜2-3 μm) regimes. The source of this bimodal size distribution is likely derived from the powder preparation process. As pressure increases between these samples, the percentage of large grains increases, as expected, due to the increased total amount of energy present during the sintering process.

### 3. Comparison Between Conventional Sintering and FAST

To complement the analysis of CsPbBr₃ pellets fabricated via FAST, FAPbBr₃ pellets were pressed via conventional cold pressing and subsequent annealing. FIG. 10 shows fracture surface SEM of FAPbBr₃ conventionally pressed pellets as a function of increasing pressure and annealing. Investigating the fracture surface of these pellets, it is clear that pellets pressed by conventional sintering are substantially less dense than FAST sintered samples. This is because FAST applies several different energy sources (pressure, temperature, electric field) that induce neck growth and subsequent grain growth to reduce porosity of the compact. Furthermore, the joule heating in FAST induces localized phenomena not present in conventional sintering, including localized evaporation and melting, driving more rapid densification. The FAPbBr₃ pellets only have the application of one energy source at a time (uniaxial pressure, then temperature) which limits efficient, microstructure tailorable pellet densification. In the FAPbBr₃ pellets pressed without thermal energy, clear neck growth between individual particles can be seen even without annealing, suggesting that this neck growth is simply pressure induced. When the pellets are annealed, the average grain size appears to grow and porosity reduces slightly. However even with annealing, overall porosity is visibly high, especially compared to the sintered sample. High porosity may have two negative effects in performance: 1) reduced effective X-ray attenuation due to decreased density, and 2) suppressed electron mobility as electrons cannot transport effectively through the pores.

FIG. 11 shows a comparison between a conventional sintered perovskite sample, pressed at 100 MPa, annealed at 140° C. for 15 minutes and a FAST perovskite sample, pressed at 40 MPa, 100° C. for 10 minutes. Due to substantially densification and grain growth seen due to application of an applied electric field in FAST, high density can be achieved within minutes.

### 4. Radiation Detectors

A radiation detector can be a semiconducting material with two or more electrodes deposited onto the surface. One set of electrodes collects electrons, and the other set collects holes. The electrodes can be deposited in a variety of configurations and geometries, including but not limited to planar electrodes, pixelated electrodes, asymmetric electrodes, imbedded electrodes, multilayered electrodes, p-i-n configured electrodes, etc. The semiconductor material itself has a wide range of potential properties including a band gap ˜0.5-6 eV, resistivity ranging from 10⁶-10¹⁴ Ohm cm, and features the ability to convert absorbed photons into electron-hole pairs.

Once the pellet is fabricated, the surfaces are polished using chemo-mechanical methods in order to obtain a very smooth finish. Once polished, the detectors are passivated (i.e. oxide grown on top of the crystal) using a wide variety of methods including plasma treatments, etching, heat treatments, thermochemical reactions, thin film deposition, atomic layer deposition, etc. Then, electrodes are deposited via physical vapor deposition techniques such as thermal evaporation, electron-beam evaporation, or sputtering. Electrode materials can be comprised of any metal, metal-nitride, metal-carbide, or metal oxide. Examples of electrode materials include, but are not limited to, gold, silver, carbon, titanium, vanadium, chromium, iron, nickel, copper, zinc, gallium, aluminum, silicon, zirconium, niobium, molybdenum, palladium, ruthenium, indium, tin, hafnium tantalum, tungsten, rhenium, iridium, platinum, lead, bismuth, and subsequent nitrides, carbides, oxides, dopants, mixed concentration, etc. Specific nitrides, carbides, and oxides include titanium nitride, vanadium nitride, chromium nitride, tungsten nitride, aluminum nitride, titanium aluminum nitride, zirconium nitride, hafnium nitride, niobium nitride, titanium oxide, chromium oxide, vanadium oxide, iron oxide, copper oxide, zinc oxide, indium oxide, indium tin oxide, tin oxide, aluminum oxide, aluminum zinc oxide, nickel oxide, magnesium zinc oxide, copper chromium oxide, titanium carbide, aluminum carbide, chromium carbide, hafnium carbide, tantalum carbide, tungsten carbide, zirconium carbide, niobium carbide, vanadium carbide, and mixed compositions and dopants thereof.

Prototype X-ray detectors were fabricated by sputtering gold (Au) contacts on the front and back of the FAST sintered samples to form vertical Au/CsPbBr₃/Au structures, as shown in FIG. 12. Bulk resistivity was studied by measuring the IV characteristics of the Au/CsPbBr₃/Au structures as a function of increasing sintering pressure, as shown in FIG. 13. Increasing the applied load from 10-40 MPa resulted in a non-linear decrease in bulk resistivity. The 10 MPa and 20 MPa samples exhibit similar resistivity values of 2.38×10⁹ and 1.94×10⁹ Ωcm respectively, as shown in FIG. 13. These values are slightly more resistive than that of the single crystal (9.3×10⁸). What was unexpected is the pellets pressed at 30 and 40 MPa having substantial decreases in resistivity (6.22×10⁸ and 6.44×10⁸ Ωcm respectively), which are both lower than that of the single crystal.

The microstructure of the sintered compacts imaged in FIG. 9 can help explain the resistivity trends seen in the pellets. In FIG. 9, as pressure increases between these samples, the percentage of large grains increases due to the increased total amount of energy present during the sintering process. This trend can help explain the observed changes in resistivity. In the smaller grain size mode regions, charge transport is inhibited by the large number of grain boundaries increases the distance an electron must travel to reach the electrode. However, as we increase the percentage of large grains present in the larger pressure samples, the number of overall grain boundaries decreases. These grain boundaries likely serve as fast conduction pathways, thus lowering the overall resistivity past that of the single crystal. The balance between increased electron mobility along the grain boundaries and the overall distance electrons can travel explains the observed resistivity trends well.

Low work function contacts are needed to form a rectifying junction with CsPbBr₃. TIN was selected due to its work function and low reaction probability with CsPbBr₃, as shown in FIG. 14. TiN/CsPbBr₃/Au devices were fabricated from FAST sintered pellets and observed for their rectifying behavior. While the pellets sintered at 10 and 20 MPa exhibited rectifying behavior, the 30 and 40 MPa pellets appear to be more Ohmic, as shown in FIG. 15. Two phenomena may explain this observed loss in rectification. As the powders are pressed, they come into direct contact with Ta foil, which could diffuse into the CsPbBr₃ pellet. This could result in the fermi level slightly changing due to doping concentration, which would dictate whether the TiN would form an Ohmic or a Schottky junction. Further investigation via ultraviolet photoelectron spectroscopy would give insight into the specific band structure energies and determine if this theory is valid. Alternatively, the devices fabricated out of the 30 and 40 MPa pellets may simply have higher leakage current which overwhelm any rectifying properties present in the contacted structure. This excess leakage may be due to poor surface preparation, or excess current more easily flowing around the device due to decreased bulk resistivity. Compared to the single crystals, the pellets that exhibit rectifying behavior have roughly the same order of magnitude dark current density (˜100 nA/cm²) at −500 V/cm applied electric field. This is expected as the current flowing through the potential barrier under reverse bias is associated with primarily surface leakage, suggesting that the surface quality of the polished single crystal and pellet are similar.

Radiation detectors require small measured currents under high applied voltage. This is generally dictated by the bulk resistivity of the semiconductor. If the semiconductor has a high enough bulk resistivity (˜10¹⁰⁻¹¹ Ωcm), an ohmic contact structure is preferred. If the semiconductor has a low bulk resistivity (˜10⁸⁻⁹ Ωcm) a rectifying junction is needed. For the example of CsPbBr₃, the rectifying junction is necessary for radiation detection.

Radiation detectors and radiation shielding both feature the ability to interact with high energy particles, charge particles, neutrals, neutrons, etc. In a radiation detector, energy is absorbed, resulting in the production of electron-hole pairs. These electron-hole pairs are then extracted from the detector under an applied electric field, and collected by the electrodes. This charge collection allows for the detection of ionizing radiation, particles, neutrons, etc. In a radiation shield, the primary goal is to absorb, reflect, deflect, or scatter photons, ions, particles, neutrons, etc. The radiation shield may or may not generate electron-hole pairs under irradiation. There does not need to be a conduction pathway through the bulk to monitor radiation interactions for a radiation shield. Radiation shields can take a variety of forms including bulk material, nanostructured material, multilayered material, composite material, nanostructured composite materials, etc.

Engineering smooth surface of MHP crystals has experienced several challenges. First, MHPs dissolve in water, rendering traditional polishing methods not viable. Second, MHPs also degrade in alcohols, making most commercial alternatives to water not viable as well. Third, MHPs have low hardness and are very brittle, making crystals prone to fracture under light loads. Soft media such as silica, ceria, kaolin, and/or talc can be incorporated to reduce surface roughness.

Various surface passivation strategies are investigated to decrease leakage current and potentially reduce surface driven ionic diffusion. FAPbBr₃ crystals are prepared with various surface preparation such as Alumina based polish, UV-Ozone oxidation, SiO2 coating via PE-ALD, or PEABr passivation.

Similar to the high pressure CsPbBr₃ FAST pellets, the resistivity of the conventionally sintered pellets is substantially lower than the single crystal (polycrystalline ˜10⁷ Ωcm, single crystal ˜10⁸ Ωcm) even with the fairly high porosity present throughout the bulk. This suggests that the electron mobility is substantially higher along the grain boundaries and free surfaces compared to the bulk, as expected. With the Au/FAPbBr₃/Au contact structure applied to these samples, the dark current measured is quite high, reaching the μA range. High dark currents result in large noise at high applied biases, which limits this device to low voltage operation. Application of a TiN rectifying contact will substantially lower dark current and allow the device to be operating at high reverse bias.

In application, CsPbBr₃ single crystals will be operated at high reverse bias. TiN/CsPbBr₃/Au devices exhibited 100 nA/cm2 dark current at 500 V/cm applied electric field, as shown in FIG. 16, on par with liquid Ga contacts, while being more environmentally robust. Short term biasing results in fairly repeatable dark currents measured.

IV characteristics of TiN/CsPbBr₃/Au device showed a hysteresis behavior as voltage is swept from −20 to +20 V, and back, as shown in FIG. 17. This is likely not a ferroelectric effect due to lack of spontaneous polarization in CsPbBr₃. FIG. 18 shows that increasing hold time (Hold at +5V before measurement) resulted in increased measurement stability and reduced dark currents. FIG. 19 shows that increasing sweep delay substantially decreased stability and increased dark currents. Devices will need to be optimized to account for ionic contributions to dark currents.

X-ray sensitivity of the FAPbBr₃ pellets was measured as a function of applied pressure and annealing conditions. Samples were exposed to increasing X-ray doses under a constant 2 V applied forward bias. X-ray sensitivity can be described as the amount of charge collection per unit of absorbed dose. Absorbed dose is measured in units of Gray (Gy), and an applied dose rate is simply measured in Gy/s. The measured photo current density (A/cm²) vs. the dose rate (mGy/s) plotted and a linear slope is extracted to be the amount of charge collected per unit dose, or the X-ray sensitivity (μC Gy⁻¹ cm⁻²), as shown in FIG. 20. The X-ray sensitivity substantially increases from 18.02±0.4 to 168.6±13.79 μC Gy⁻¹ cm⁻² as a function of applied pressure during sintering. This result matches well with the observed microstructural trends. Sensitivity also increased with a post anneal, again matching with the microstructural analysis. Comparing to the current state-of-the-art detector, a-Se, the FAPbBr₃ detector is ˜6-9× more sensitive. Additionally, the FAPbBr₃ sample was measured under an applied electric field of 0.005 V/μm, compared to a-Se which is generally operated at 10 V/μm. Since X-ray sensitivity is directly proportional to applied electric field (i.e. higher applied electric field, higher measured sensitivity), the FAPbBr₃ has substantial potential for even higher X-ray sensitivities if operated at higher voltages. However, the current device structure has a fundamental limitation of low bias operation due to both high dark currents and fairly high ionic mobility, which can further increase dark currents. Future developments in contact engineering and vacancy concentration may be able to allow this device to be operated at a higher bias regime, thus increasing sensitivity even further past the current state-of-the-art. It is expected that the X-ray sensitivity will further increase by utilizing FAST to consolidate metal-halide perovskite, double perovskite, and/or novel wide band gap semiconducting powders due to the enhanced microstructure and more efficient charge transport.

As will be clear to those of skill in the art, the embodiments of the present invention illustrated and discussed herein may be altered in various ways without departing from the scope or teaching of the present invention. Also, elements and aspects of one embodiment may be combined with elements and aspects of another embodiment. It is the following claims, including all equivalents, which define the scope of the invention.

1. A method of fabricating or synthesizing a polycrystalline crystal of a radiation sensitive material used for radiation detectors and shielding, respectively, the method comprising the steps of:
providing constituent powders or a single crystal material of the radiation sensitive material or a mixed combination thereof;
forming a single phase powder of the radiation sensitive material via solid-state thermochemical and/or thermomechanical reaction between constituent powders or milling the single crystal material of the radiation sensitive material into powders; and
pressing the single phase powder of the radiation sensitive material via Field Assisted Sintering Technology to form a pellet, component or structure of the polycrystalline radiation sensitive material.

2. The method according to claim 1, further comprising embedding the powder of the radiation sensitive material into matrix material before pressing.

3. The method according to claim 2, wherein the matrix material is polymeric fibers or plastics.

4. The method according to claim 1, wherein the radiation sensitive material includes metal halide perovskites, metal halide double perovskites, and high-Z materials.

5. The method according to claim 1, wherein the radiation sensitive material is CsPbBr₃, the constituent powders are CsBr and PbBr.

6. The method according to claim 5, further comprising pre-milling the CsBr powder so that the CsBr and PbBr powders have a particle size on the same order of magnitude.

7. The method according to claim 1, wherein the milling technique is used to form the single phase powder of the radiation sensitive material, the milling technique includes ball milling, attrition milling, cryogenic milling, shaker jar milling.

8. The method according to claim 1, wherein a temperature for FAST is in a range of from −100° C. to 0.95T_{M}, T_{M} is melting temperature of the material.

9. The method according to claim 1, wherein a pressure for FAST is in a range of from 0 MPa to 200 MPa.

10. The method according to claim 1, wherein the pellet is up to 14″ in diameter.
